(19) United States
(12) Patent Application Publication
(10) Pub. No.: US 2026/0068236 A1
(43) Pub. Date: Mar. 5, 2026

(54) TRENCH-BASED SUPER JUNCTION STRUCTURES VIA SIDEWALL DOPING

(71) Applicant: Applied Materials, Inc., Santa Clara, CA (US)

(72) Inventors: Amirhasan NOURBAKHSH, Albany, NY (US); Michael CHUDZIK, Mountain View, CA (US)

(73) Assignee: Applied Materials, Inc., Santa Clara, CA (US)

(21) Appl. No.: 18/819,904

(22) Filed: Aug. 29, 2024

(51) Int. Cl. H01L 29/06; H01L 21/02; H01L 21/311; H01L 21/3115

(52) U.S. Cl. CPC H10D 62/102

(57) ABSTRACT

A super junction device with an increased voltage rating may be formed by decreasing the width of the P-type region and increasing the doping concentration, while also increasing the height of the overall device. A trench may be etched for both a P-type region and an adjacent N-type region. This allows the height of the overall device to be increased while maintaining a feasible aspect ratio to fill the trench. The P-type material may then be formed by doping the sidewalls of the trench for a P-type layer that is relatively thin compared to the remaining width of the trench. The trench may then be filled with N-type material such that the P-type region fills the space between the N-type regions without any voids or seams, while having a width that would be unattainable using traditional etch-and-fill methods for the P-type region alone.

### TECHNICAL FIELD

The present technology relates to semiconductor systems, processes, and equipment. More specifically, the present technology relates to processes and systems to improve scaling for high aspect ratio super junction devices.

### BACKGROUND

Integrated circuits are made possible by processes which produce intricately patterned material layers on substrate surfaces. Producing patterned material on a substrate requires controlled methods for forming and removing material. As device sizes continue to reduce, features within the integrated circuits may get smaller and aspect ratios of structures may grow, and maintaining dimensions of these structures during processing operations may be challenged. Specifically, high-aspect-ratio devices may require relatively deep features to be etched in the active material. However, as aspect ratios increase so does the difficulty of etching straight features and later filling those features uniformly without seams or gaps.

Thus, there is a need for improved systems and methods that can be used to produce high quality devices and structures. These and other needs are addressed by the present technology.

### SUMMARY

In some embodiments, a method of forming a super junction device, may include forming a first N-type material on a substrate; etching a trench in the first N-type material, where the trench may form at least a first N-type region from the first N-type material; causing a sidewall of the trench comprising the first N-type region to be doped with a P-type dopant to form a P-type region in the first N-type region; and filling the trench with a second N-type material to form a second N-type region such that the P-type region may be between the first N-type region and the second N-type region.

In some embodiments, a method of forming a super junction device may include etching a trench in a first N-type material on a substrate, where the trench may form at least a first N-type region from the first N-type material; forming a P-doped layer on a sidewall of the trench comprising the first N-type region, where the P-doped layer may include a P-type dopant; annealing the P-doped layer sufficiently to cause the P-type dopant to diffuse into the first N-type region, thereby forming a P-type region in the first N-type region; and filling the trench with a second N-type material to form a second N-type region such that the P-type region is between the first N-type region and the second N-type region.

In some embodiments, a method of forming a super junction device may include etching a trench in a first N-type material, where the trench may form at least a first N-type region in the first N-type material; performing a plasma doping (PLAD) operation on a sidewall of the trench comprising the first N-type region, where the PLAD operation may dope the sidewall with a P-type dopant; annealing the sidewall sufficiently to cause the P-type dopant to diffuse into the first N-type region, thereby forming a P-type region in the first N-type region; and filling the trench with a second N-type material to form a second N-type region such that the P-type region is between the first N-type region and the second N-type region.

In any embodiments, any and all of the following features may be implemented in any combination and without limitation. The method may also include causing the sidewall of the first N-type region in the trench to be doped with the P-type dopant also causes a bottom of the trench to be doped with the P-type dopant. Etching the trench in the first N-type material may cause the trench to extend down from a top surface of the first N-type material, and a bottom of the trench may include at least a portion of the first N-type material between the bottom of the trench and the substrate such that the substrate is not exposed at the bottom of the trench. The method may also include forming a protective oxide layer on the P-type region and a bottom of the trench. The protective oxide layer may be between about 5 nm and about 15 nm thick and is formed conformally inside of the trench. The method may further include performing a directional etch downward into the trench to remove a P-doped region at a bottom of the trench without removing the P-type region along the sidewall of the trench. The method may also include removing a protective oxide layer on the P-type region after performing the directional etch, where the directional etch may also remove a protective oxide layer on the bottom of the trench. The directional etch need not expose a top surface of the substrate at a bottom of the trench. The P-doped layer may include boron-doped silicon oxide formed using a deposition operation. The P-doped layer may include boron-doped silicon nitride formed using a deposition operation. The P-doped layer may include borophosphosilicate (BPSG) glass. The P-doped layer may be between about 50 nm and 150 nm thick. Annealing the doped layer may include applying a temperature that is between about about 700° C. and about 1100° C. The P-type dopant may diffuse into the first N-type region to a depth of between about 100 nm and about 200 nm. The P-type dopant may diffuse into the first N-type region to a concentration of between about 5e16 atoms/cm³ and about 5e17 atoms/cm³. A height of the P-type region may be greater than or about 70 μm. A combined width of the P-type region and the second N-type region may be less than or about 4 μm. An aspect ratio of an area occupied by second the N-type region and the P-type region may be less than or about 20.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 shows a top plan view of one embodiment of a processing system of deposition, etching, baking, and curing chambers that may be included or configured according to some embodiments of the present technology.

FIG. 2 illustrates a super junction device, according to some embodiments.

FIG. 3 illustrates a flowchart of a method for forming a super junction device, according to some embodiments.

FIGS. 4A-4I illustrate incremental structures as an asymmetric super junction device is formed, according to some embodiments.

FIG. 5 illustrates how a P-type region may be formed in the N-type material using a plasma doping (PLAD) technique, according to some embodiments.

### DETAILED DESCRIPTION

A super junction device with an increased voltage rating may be formed by decreasing the width of the P-type region and increasing the doping concentration, while also increasing the height of the overall device. However, instead of etching a trench in the N-type material to fill with the P-type material, a trench may be etched for both the P-type region and an adjacent N-type region. This allows the height of the overall device to be increased while maintaining a feasible aspect ratio for the trench. The P-type material may then be formed by causing a sidewall of the trench to be doped with a P-type dopant. The P-type dopants may be placed in the sidewall of the trench using a plasma doping (PLAD) operation followed by an anneal to cause the P-type dopant to diffuse into the N-type material. Alternatively, a doped P-type layer may be deposited or otherwise formed on the sidewalls of the trench. A subsequent anneal process may cause the P-type dopant from that layer to diffuse into the N-type layer to a desired depth and concentration. The trench may then be filled with N-type material such that the thin P-type region fills the space between the N-type regions without any voids or seams, while having a width that would be unattainable using traditional etch-and-fill methods for the P-type region alone.

As device sizes continue to shrink, many material layers may be reduced in thickness and size to scale devices. Features inside semiconductor structures may be reduced in size, and aspect ratios of the features may increase. As the aspect ratios of the features increase, patterning operations may struggle to uniformly etch features without tapering the sidewalls of the feature, or compromising feature dimensions or integrity, due to increased exposure nearer a surface of the substrate material being processed. Further, refilling a feature with higher aspect ratios may be increasingly difficult due to pinch off at the top of the feature that prevents the feature from being filled without seams and/or voids.

In forming power device structures, conventional technologies have been limited in device scaling for increased aspect ratio features based on the natural effects of prolonged etching and deposition operations. For example, in super junction structures, p-type silicon pillars are formed by filling trenches etched into n-type silicon with p-type material. In these structures, the on-resistance is controlled by the pitch or width of the different materials. The resistance may be improved by reducing the width of the p-type silicon pillars. Scaling the p-type silicon pillars is limited by etching and seam and/or void free trench filling capabilities. For example, increasing the aspect ratio with conventional etching may cause pitch degradation and tapered features due to the prolonged exposure of upper regions of the feature being formed. Additionally, the fill operation of high-aspect ratio features may lead to pinch off before deeper regions of the feature are filled. Consequently, conventional technologies have been limited to lower aspect ratios, or shorter structures to limit performance effects or device failure. Accordingly, many conventional technologies have been limited in the ability to prevent structural flaws in the final devices or improve on historical designs.

The present technology overcomes these issues by redefining the way in which the pillars are formed in the base material. By forming a thin doped layer on a sidewall of the trench in the N-type material prior to backfill, the P-type regions or pillars of material can be maintained at much smaller widths compared to conventional technologies. More specifically, the width of the P-type pillars may be defined by the width of the doped region rather than the width of the recessed features. In fact, the recessed features can be made wider than conventional technologies as two P-type pillars may be formed by doping both sidewalls of each recessed feature. After doping the sidewalls with P-type material, the recessed features may be backfilled with additional base material. By changing the formation process itself, the present technology may afford much greater aspect ratio features, and also may prevent or reduce defects in final devices based on more uniform fill and coverage.

Although the remaining disclosure will routinely identify specific etching and deposition processes utilizing the disclosed technology, it will be readily understood that the systems and methods are equally applicable to a variety of other processes as may occur in the described chambers. Accordingly, the technology should not be considered to be so limited as for use with the described etching or deposition processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems.

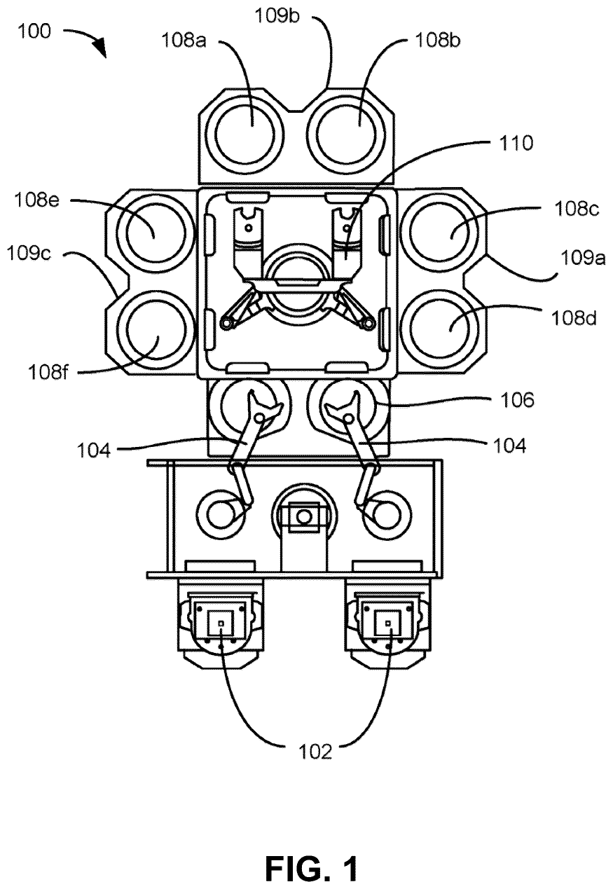

FIG. 1 shows a top plan view of one embodiment of a processing system 100 of deposition, etching, baking, and curing chambers that may be included or configured according to some embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

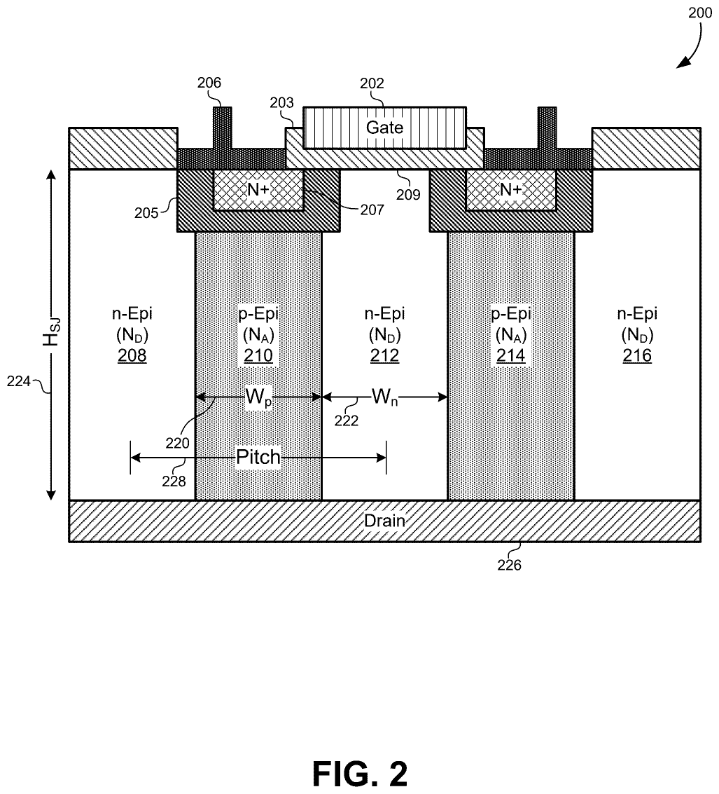

System 100, or more specifically chambers incorporated into system 100 or other processing systems, may be used to produce structures according to some embodiments of the present technology. FIG. 2 illustrates a super junction device 200, according to some embodiments. The device 200 in FIG. 2 is represented by example as a super junction transistor, such as a super junction MOSFET. However, the principles described herein may be used to form any super junction device, and the description is not limited to a super junction transistor.

The device 200 may include a number of different electrical contacts. The device 200 may include a source contact 206 that is electrically coupled to an N+ source region 207 that is formed within a P-well 205. Collectively, the source contact 206, the N+ source region 207, and the P-well 205 may be referred to as a “source region” of the device 200. The device may be formed on a silicon substrate 226. The silicon substrate 226 may form a drain region of the device 200. Although not shown explicitly in FIG. 2, the drain region formed by the substrate 226 may include a conductive contact similar to the source contact 206. The device 200 may also include a gate region that includes a gate contact 202 and a gate oxide 209. Each of the source, drain, and gate regions may include other layers or regions that are not explicitly shown in FIG. 2. Additionally, these contacts may also be referred to in this disclosure more generically as a “first,” “second,” and “third” contact to distinguish one contact from the other in a manner that is not specific to a transistor. For example, in this transistor implementation, the drain region may be referred to as a first contact region, the gate region may be referred to as a second contact region, and the source region may be referred to as a third contact region.

The internal regions of the device 200 may include a plurality of N-doped regions and/or P-doped regions. These regions may also be referred to as “pillars,” as these regions typically extend from the silicon substrate 226 up to the top of the device 200. The device 200 may include a first N-type region 208 that extends orthogonally up from the silicon substrate 226 to the top of the device 200. The device 200 may also include a P-type region 210 that also extends orthogonally up from the silicon substrate 226 to the source region of the device 200. The device 200 may also include a second N-type region 212 that similarly extends orthogonally up from the silicon substrate 226 to the gate region. Note that the device 200 may also include additional contact regions, P-type regions (e.g., P-type region 214), and N-type regions (e.g., N-type region 216), some of which are illustrated in FIG. 2.

Typically, the width 220 of the P-type region 210 and the width 222 of the second N-type region 212 are approximately the same in standard super junction devices. Additionally, a doping level (NA) of the P-type region 210 and a doping level (Np) of the N-type region 212 are also equal. In order to function optimally, the charge should be balance between the second N-type region 212 and the P-type region 210 according to the following equation.

$${N}_{A} {W}_{p} = {N}_{D} {W}_{n} \qquad ( 1 )$$

With careful charge balancing between the N-type pillars in the P-type pillars in the device 200, these regions may completely deplete each other to form a depletion region throughout the bulk of the device 200. Full depletion increases the breakdown voltage of the device 200 significantly without lowering the doping concentrations. This allows the device to have very high doping concentrations in the N-type regions so long as the balance is maintained according to equation (1) above.

The breakdown voltage of the device 200 is also a function of the height 224 of the device 200. Typically, the greater the height 224 of the device 200, the higher the breakdown voltage of the device 200. However, manufacturing limitations have limited the height 224 of the device 200 due to aspect ratios of the features. Specifically, forming the device typically includes forming an N-type material on top of the silicon substrate 226. Trenches are then etched in the N-type region, leaving N-type mesas that include, for example, N-type region 208, N-type region 212, and so forth. The trenches are then filled with the P-type material to form the P-type regions, such as P-type region 210, P-type region 214, and so forth. Therefore, the aspect ratio of the trench limits the depth of the trench unless the width of the trench is increased. However, increasing the width of the trench increases the total size of the device 200. With shrinking device sizes, increasing the size of the device to increase the breakdown voltage is not a feasible option in most applications.

For example, the device 200 in FIG. 2 may be rated as a 650 V device. The specifications for this 650 V device include a height 224 of about 40 μm. The width 220 of the P-type region 210 is about 2 μm (also referred to as a critical dimension or “CD”). This leads to an aspect ratio of 40/2=20 for a trench that is etched to form the P-type region 210. The pitch 228 is about 4 μm, which may be defined as the distance between centers of consecutive N-type regions. The aspect ratio of 20 has been found to be an acceptable feature size for current etch and fill operations for devices of this size. Increasing the aspect ratio beyond 20 at this size can cause problems when etching the trenches. Specifically, the trenches may erode at the top surface of the trench, and may develop sloped sidewalls with a poorly defined bottom in the trench. Increasing the aspect ratio may also cause problems when filling the trenches. When depositing material in the trenches, the material may close off the trench at the top before the trench is filled throughout the height of the trench. This may cause voids or seams in the P-type regions that interfere with the operation of the device 200.

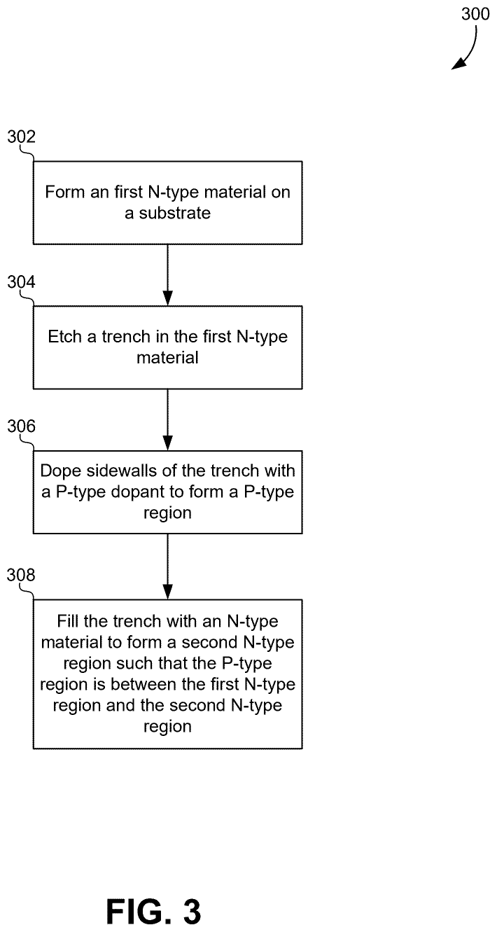

FIG. 3 illustrates a flowchart of a method 300 for forming a super junction device, according to some embodiments. The super junction device formed by method 300 may be referred to as an “asymmetric” super junction device. For example, traditional super junction devices use equal widths for neighboring N-type and P-type regions. In contrast, method 300 forms a super junction device with a relatively thin P-type region in comparison to the N-type region. These very narrow P-type “pillars” reduce the pitch of the PN junction and allow wider trenches to be formed and more reliably filled with N-type material. Method 300 may be performed in one or more processing chambers, such as chambers incorporated in the system 100 described above. Method 300 may or may not include one or more operations prior to the initiation of the method, including front-end processing, deposition, etching, polishing, cleaning, or any other operations that may be performed prior to the described operations. Method 300 may also include a number of optional operations as denoted in the figure, which may or may not be specifically associated with some embodiments of methods according to the present technology.

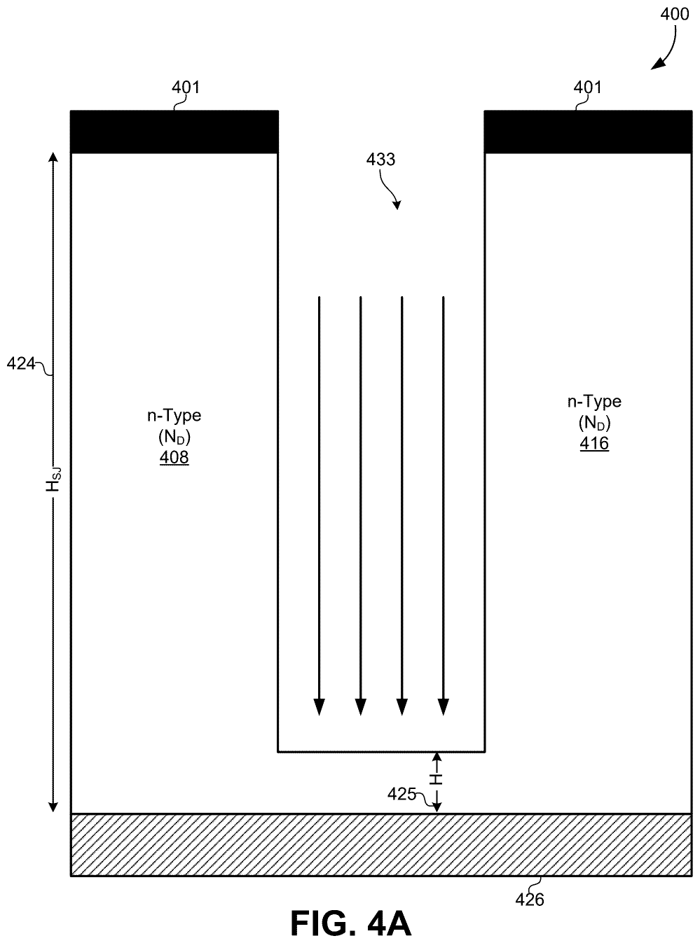

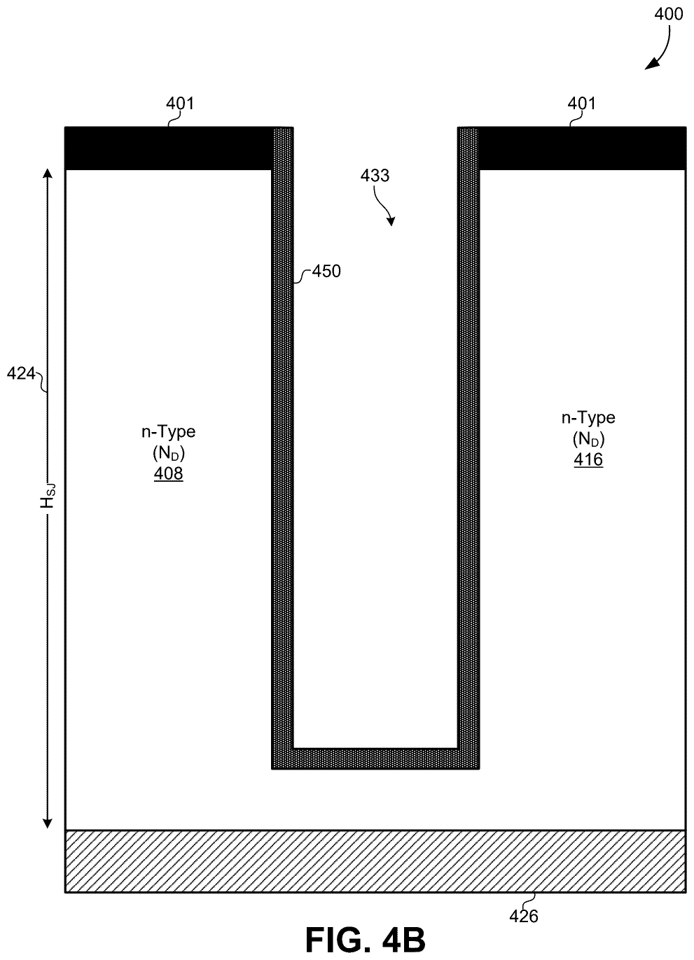

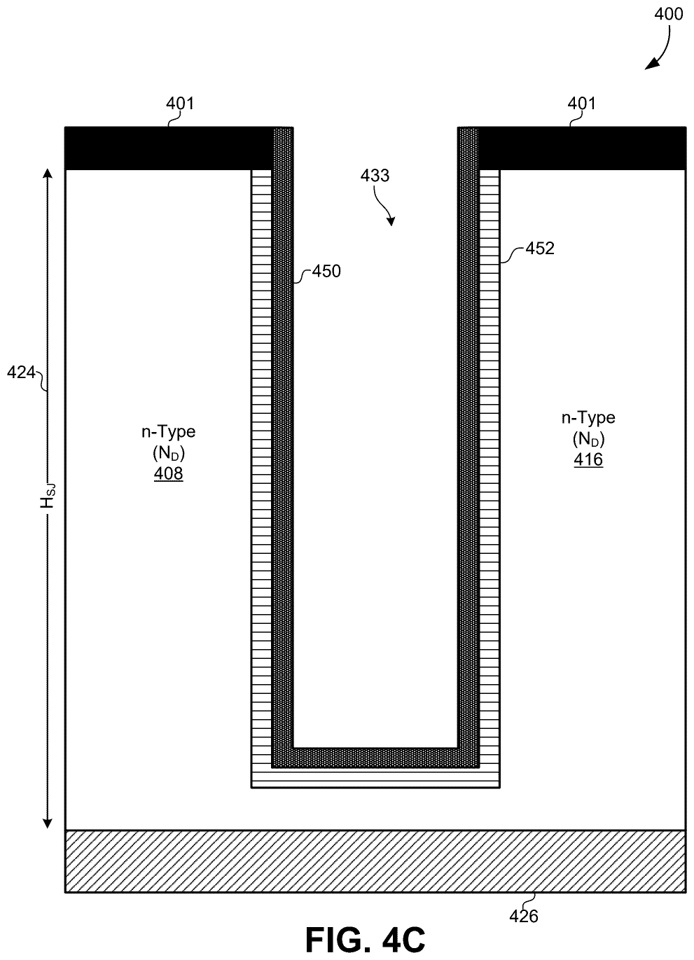

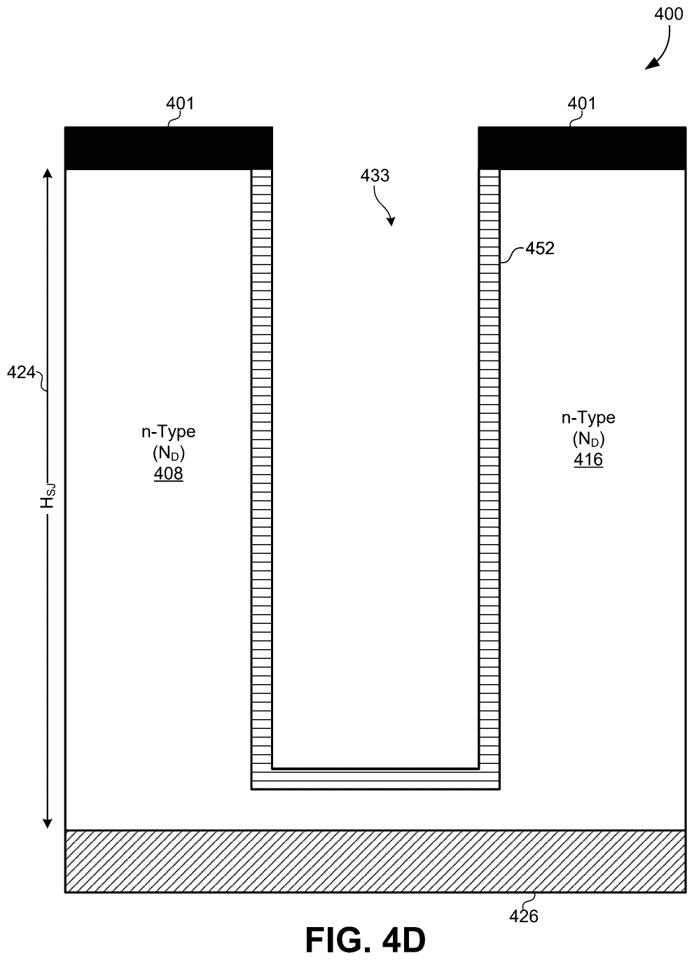

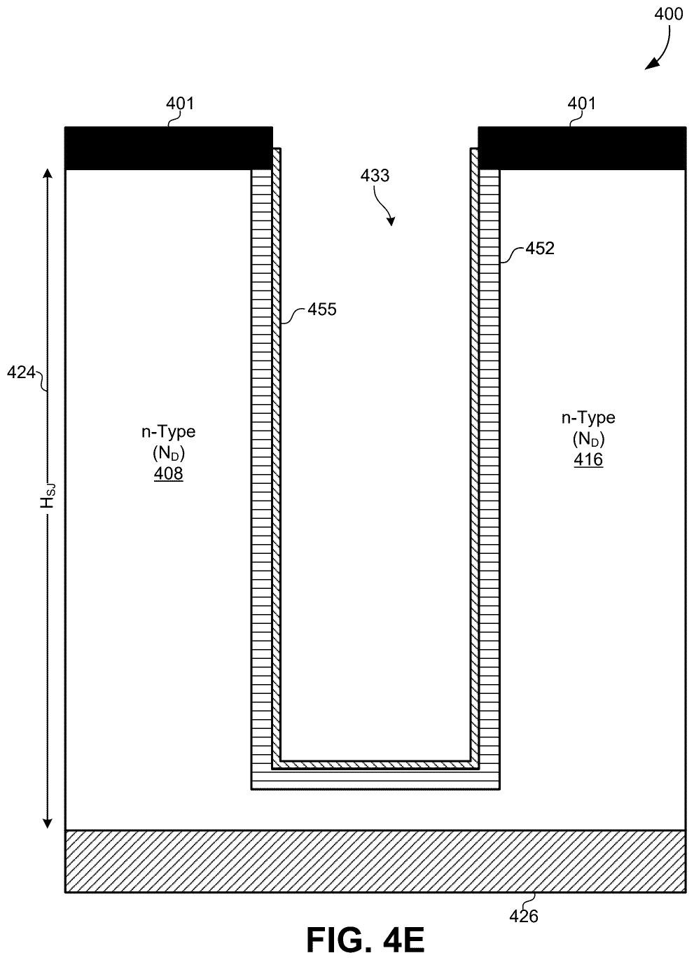

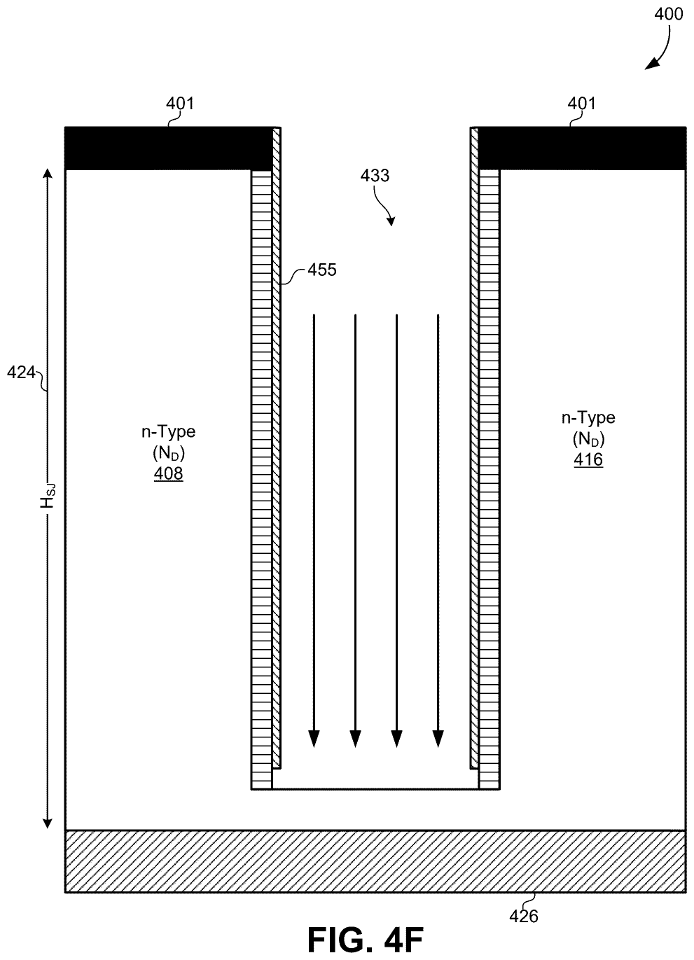

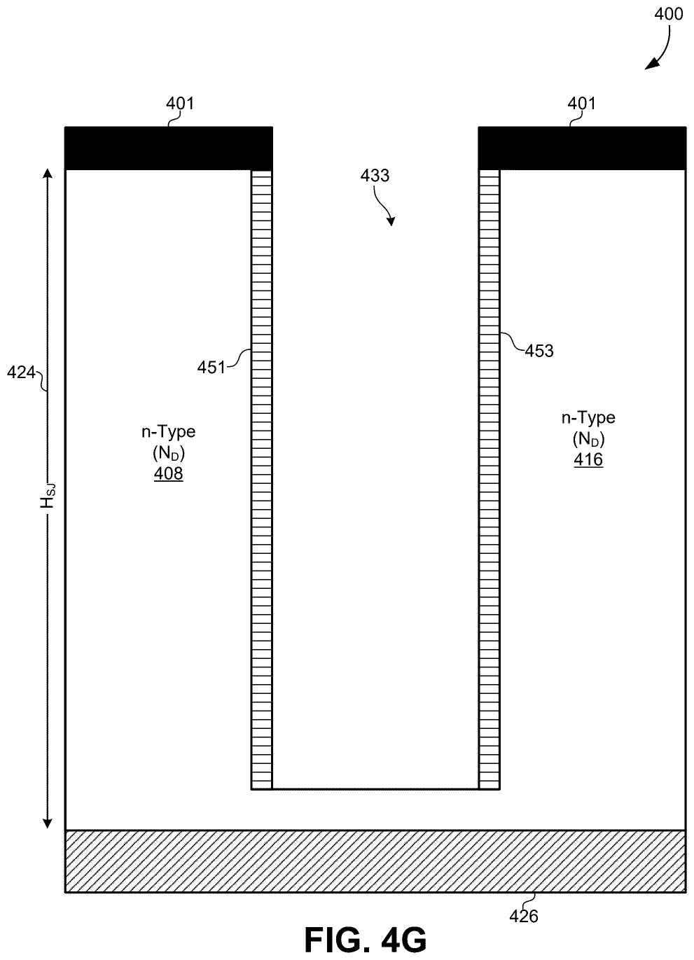

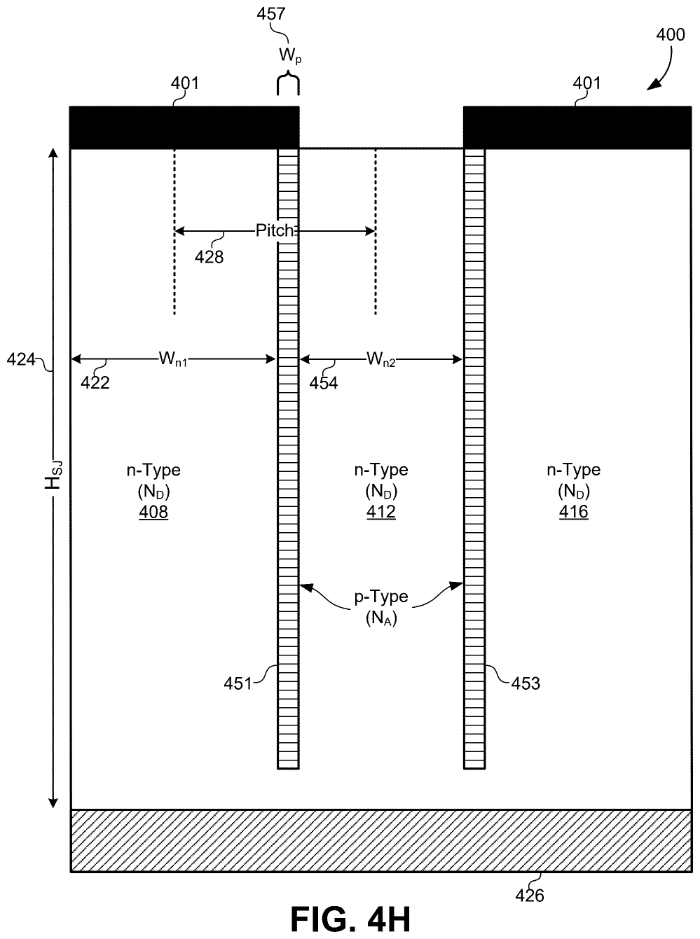

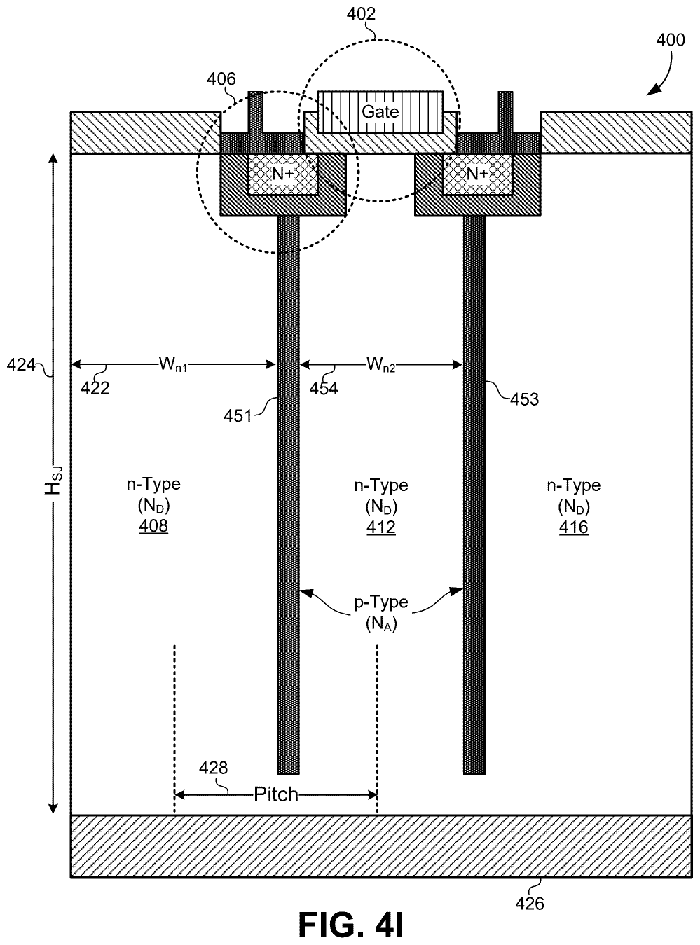

FIGS. 4A-4I illustrate incremental structures as an asymmetric super junction device is formed, according to some embodiments. FIGS. 4A-4I will be referenced as examples of how the operations of the method 300 may be performed. However, the structures of FIGS. 4A-4I are provided only by way of example, and are not meant to limit the operations of method 300. Instead, method 300 may be used to form any type of super junction device without limitation. It is to be understood that these figures illustrate only partial schematic views with limited details, and in some embodiments a substrate may contain any number of semiconductor sections having aspects as illustrated in the figures, as well as alternative structural aspects that may still benefit from any of the aspects of the present technology.

The method 300 may include forming a first N-type region over a substrate (302). As illustrated in FIG. 4A, a structure 400 may include a substrate 426. The substrate 426 may have a substantially planar surface or an uneven surface in various embodiments. The substrate 426 may be a material such as crystalline silicon, silicon oxide, strained silicon, silicon germanium, doped or undoped polysilicon, doped or undoped silicon wafers, patterned or non-patterned wafers, silicon on insulator, carbon doped silicon oxides, silicon nitride, doped silicon, germanium, gallium arsenide, or sapphire. As one non-limiting example, in some embodiments the substrate may be or include an N+ material, such as N+ silicon. The substrate 426 may have various dimensions, such as 200 mm or 300 mm diameter wafers, as well as rectangular or square panels. The substrate 426 may be disposed within the processing region of the semiconductor processing chamber. Although shown as a planar substrate, it is to be understood that substrate 426 is included merely to represent an underlying structure, which may include any number of layers or features on a wafer or other substrate, and over which structures as described below may be formed.

Above the substrate 426, the structure 400 may include a first N-type material. The first N-type material may be disposed along at least a portion or all of the substrate 426. The first N-type material may include a silicon-containing material such as N-type silicon, which may be doped with phosphorous, arsenic, a combination of both, or other similar materials. More generally, any of the N-type material and/or P-type materials may be formed using any silicon, silicon carbide, silicon germanium, GaN, AlGaN materials or other similar materials. The N-type and P-type materials may be epitaxially deposited semiconductor material. For example, the resulting N-type and P-type regions of the super junction device may be formed using doped silicon carbide rather than doped silicon. The first N-type material may form the first N-type region 408, although the mesa or pillar of the first N-type region 408 (and possibly other N-type regions 416) may not become apparent until after a trench is etched in the following operation. The height 424 of the first N-type material and the subsequent first N-type region 408 may be greater than or about 20 μm, between about 20 μm and about 30 μm, between about 30 μm and about 40 μm, between about 40 μm and about 50 μm, between about 50 μm and about 60 μm, between about 60 μm and about 70 μm, between about 70 μm and about 80 μm, greater than or about 80 μm, and so forth. For example, a device having a 1300 V breakdown voltage may have a first N-type region 408 that is about 80 μm high. For devices having a breakdown voltage greater than 650 V, the height of the first N-type region 408 may be greater than or about 50 μm, greater than or about 60 μm, greater than or about 70 μm, and/or greater than or about 80 μm. Other embodiments may include a first N-type region 408 that is less than about 40 μm, which may be used to form super junction devices with a smaller overall width. Other embodiments may also include a first N-type region that is greater than or about 90 μm, greater than or about 100 μm, and so forth, depending on the desired voltage characteristics of the super junction device. The height 424 of the first N-type material may also include any combination of the ranges listed above (e.g., less than or about 50 μm, between about 40 μm and about 80 μm, greater than or about 70 μm, etc.). The height 424 of the first N-type material may also include any single value within the ranges listed above (e.g., about 40 μm, about 80 μm, etc.).

In some embodiments, to facilitate patterning of the first N-type material, hard masks, photoresists, or any other mask materials may be disposed on top of the first N-type material. For example a first mask may be formed over the first N-type material, and a second mask may be formed over the first mask. In some embodiments, either or both masks may include any number of materials to promote structural formation, such as oxides, nitrides, carbides, or some combination of materials. For example, the first mask may be or include silicon nitride, and the second mask may be or include silicon oxide, or some other mask material. It is contemplated that a mask 401 comprising one or more layers or materials may be provided over the first N-type material and the embodiment depicted in FIG. 4A is merely one example structure 400.

The method 300 may also include etching a trench 433 in the first N-type material (304). As shown in FIG. 4A, a pattern may be etched or formed through the first mask and/or the second mask to form features, such as the trench 433. The trench 433 may be etched through the first mask and/or the second mask using any etching processes and any etching reagents. In some embodiments, the etching may completely remove the second mask as a pattern is transferred into the underlying N-type material. Some embodiments may leave a portion of one or more of the mask layers that may be removed in a later processing stage.

The etching of the first N-type material may form one or more trenches in the material. The trench 433 may be formed to a depth of greater than or about 10 μm, and may be formed to a depth of greater than or about 15 μm, greater than or about 20 μm, greater than or about 25 μm, greater than or about 30 μm, greater than or about 35 μm, greater than or about 40 μm, greater than or about 45 μm, greater than or about 50 μm, greater than or about 55 μm, greater than or about 60 μm, greater than or about 65 μm, greater than or about 70 μm, greater than or about 75 μm, greater than or about 80 μm, greater than or about 85 μm, greater than or about 90 μm, greater than or about 95 μm, greater than or about 100 μm, or greater. As illustrated in FIG. 4A, the trench 433 may not extend all the way down to a top surface of the substrate 426. However, in some embodiments, the trench 433 may extend down to or below a top surface of the substrate 426 such that the trench 433 exposes or penetrates the substrate 426. In some embodiments, this may provide a surface from which epitaxial silicon may be grown from the substrate 426 when filling the trench 433. Therefore, the height of the trench 433 may correspond to any of the heights described above for the first N-type region 408 or higher. For example, the trench 433 may be about 80 μm high or slightly higher when extending into the substrate 426 for a 1300 V device.

Alternatively, the trench 433 may leave a portion of the first N-type material at the bottom of the trench 433 as depicted in FIG. 4A. As will be shown below, this may keep the P-type region from extending all the way down to the substrate 426, which may provide certain benefits in the asymmetric super junction device. For example, the height 425 of the first N-type material remaining at the bottom of the trench 433 may be between about 0 μm and about 2.5 μm, between about 2.5 μm and about 5 μm, between about 5 μm and about 7.5 μm, between about 7.5 μm and about 10 μm, between about 10 μm and about 12.5 μm, between about 12.5 μm and about 15 μm, and/or between about 15 μm and about 20 μm. The height 425 of the first N-type material remaining in the bottom of the trench 433 may also include any combination of these ranges (e.g., between about 5 μm and about 10 μm). The height 425 may also include any value within these ranges (e.g. about 7.5 μm).

Note that the height 424 of the device may also be reduced to reduce the breakdown voltage proportionally, since the breakdown voltage is directly related to the height of the device. For example, the height may be reduced heights below 80 μm corresponding to a breakdown voltage of greater than or about 1200 V, greater than or about 1100 V, greater than or about 1000 V, greater than or about 900 V, greater than or about 800 V, greater than or about 700 V, or greater than or about 650 V, or less than 650 V.

The trench 433 may have an aspect ratio, or a depth-to-width ratio less than or about 50, less than or about 40, less than or about 30, less than or about 25, less than or about 20, less than or about 15, less than or about 10, or less. Additionally the trench 433 may be formed to a width of greater than or about 1.5 μm, greater than or about 2.0 μm, greater than or about 2.5 μm, greater than or about 3.0 μm, greater than or about 3.5 μm, greater than or about 4.0 μm, greater than or about 4.5 μm, greater than or about 5.0 μm, greater than or about 6.0 μm, greater than or about 7.0 μm, greater than or about 8.0 μm, greater than or about 9.0 μm, greater than or about 10.0 μm, or greater. The trench 433 may also be formed to a width of between about 1.5 μm in about 2.0 μm, between about 2.0 μm and about 2.5 μm, between about 2.5 μm in about 3.0 μm, between about 3.0 μm and about 3.5 μm, between about 3.5 μm and about 4.0 μm, between about 4.0 μm and about 4.5 μm, between about 4.5 μm, and about 5.0 μm, between about 4.5 μm and about 6.0 μm, greater than about 6.0 μm, and so forth. The width of the trench 433 may also include any combination of the ranges described above (e.g., between about 2.0 μm and about 4.0 μm). The width of the trench 433 may also include any single value within the ranges described above (e.g., about 4.25 μm).

While conventional methods may strive for etching higher aspect ratio trenches to allow for narrower and deeper P-type regions to be deposited, forming trenches with higher aspect ratios may make structural formation more difficult. Not only may it be difficult to etch high aspect ratio trenches with consistent diameters, but it may also be difficult to backfill these trenches uniformly with the P-type material. Instead, the P-type material may have seams and/or voids present due to pinch off at the top of the feature during fill. Conversely, the embodiments described herein may counterintuitively allow for relaxing the width of the trench 433 to produce smaller pitch structures or higher aspect ratio structures, which may allow for more uniform etching and subsequent backfill. Further, with an increased width of the trench 433, deeper etching of the N-type material may be afforded. As an additional benefit of deeper etching, and therefore deeper structures of material, increased breakdown voltages for power devices produced by the present technology may be afforded compared to conventional methods and technology. For example, the 650 V device 200 illustrated in FIG. 2 may have trenches etched at approximately 2 μm wide, 40 μm deep, with an aspect ratio of 20. By relaxing the width of the trench, a 1300 V device may have trenches etched at approximately 4 μm wide, 80 μm deep, still with an aspect ratio of 20. As described below, the pitch of the N-type and P-type pillars may be maintained at approximately 4 μm, such that the overall width of the 1300 V device is about the same as the width of the 650 full device 200.

The method 300 may include causing a sidewall of the trench comprising the first N-type region to be doped with a P-type dopant to form a P-type region in the first N-type region (406). A number of different methods may be used to doped the sidewalls of the trench 433 to perform the P-type region in the first N-type region 408. For example, some embodiments may deposit a layer of P-type material over the sidewalls of the trench, then use a thermal anneal process to cause the P-type dopants from the P-type material to diffuse into the first N-type region 408. Alternatively, some embodiments may use a plasma doping process to place P-type dopants in the sidewalls of the trench 433, after which a thermal anneal process may cause the P-type dopants from the plasma doping to diffuse into the first N-type region 408. Note that in contrast to other methods, this method forms the P-type region directly in the first N-type region. This may be contrasted with other methods that perform or grow a P-type liner over the sidewalls of the trench, where the P-type liner operates as the P-type region of the super junction device. The method described below causes P-type dopants to be implanted and diffused in the sidewall of the trench 433 such that the overall size of the first N-type region 408 shrinks by the resulting size of the P-type region.

FIG. 4B illustrates forming a P-doped layer 450 on a sidewall of the trench 433 comprising the first N-type region, where the P-doped layer comprises a P-type dopant, according to some embodiments. This process may represent a solid-state diffusion doping process. The P-doped layer may include any dielectric or other material that is doped with the P-type dopant. For example, some embodiments may use a dielectric such as silicon oxide that is doped with boron to a very high concentration. Other embodiments may use doped silicon nitride, Borophosphosilicate glass (BPSG), or other similar materials. The P-doped layer may be doped with a concentration of P-dopants that is between about 5% and about 10%, between about 10% and about 15%, between about 15% and about 20%, between about 20% and about 25%, between about 25% and about 30%, or greater. The concentration of P-dopants may be any combination of the ranges disclosed above (e.g., between about 5% and about 20%, greater than about 15%, etc.). The concentration of P dopants may also be any individual value in the ranges disclosed above (about 15%).

The p-doped layer 450 may be deposited or formed using deposition techniques such as chemical-vapor deposition (CVD) on the sidewall of the trench 433. In some embodiments the material may be formed conformally about the feature. The P-doped layer 450 may also be deposited by atomic layer deposition (ALD) or produced by any number of other processes to produce conformal coverage about the trench 533, such as plasma-enhanced CVD (PECVD). By having trenches characterized by a wider width, the coverage may be uniform despite the greater depth of the trench 533. The P-doped layer 450 may be characterized by a thickness of between about 50 nm and about 100 nm, between about 100 nm and about 150 nm, between about 150 nm and about 200 nm, between about 200 nm and about 250 nm, between about 250 nm and about 300 nm, greater than or about 300 nm, and so forth up to 1 μm. The P-doped layer 450 may also be characterized by a thickness of less than or about 200 nm, less than or about 150 nm, less than or about 100 nm, less than or about 90 nm, less than or about 80 nm, less than or about 70 nm, less than or about 60 nm, less than or about 50 nm, less than or about 40 nm, less than or about 30 nm, less than or about 20 nm, less than or about 10 nm, less than or about 5 nm, or less. The thickness of the P-doped layer 450 may also include any combination of the ranges described above (e.g., between about 100 nm and about 200 nm, etc.). The thickness of the P-doped layer 450 may also include any single value within the ranges described above (e.g., about 200 nm).

The P-doped layer 450 may substantially cover the sidewall portion of the first N-type region 408 in the trench 433. In some embodiments, the P-doped layer 450 may also be formed on the bottom of the trench 433. The P-doped layer 450 may be free of seams and/or voids based on the conformal coverage about the structure, even to a depth of several hundred nanometers, which may provide large improvements of performance for super junction devices compared to conventional technologies that have reduced or incomplete coverage at greater depths, as well as scam or void formation. However, it is contemplated that some pores may be present in the P-doped layer 450, depending on the formation and thickness.

FIG. 4C illustrates annealing the P-doped layer 450 sufficiently to cause the P-type dopant to diffuse into the first N-type region 408, thereby forming a P-type region 452 in the first N-type region 408, according to some embodiments. The thermal anneal process may be performed for a number of different reasons. First, the thermal anneal may diffuse the dopant deeper into the first N-type region 408 as illustrated in FIG. 4C. Additionally, the thermal anneal may activate the dopants and cause a conformal, ultra-thin P-type region 452.

The thermal anneal may be carried out at a high temperature in an inert atmosphere. For example, a gas delivery system of the processing chamber may deliver an inert gas to the processing volume, such as nitrogen or argon gas. The high temperatures of the thermal anneal process may range from between about 500° C. to about 600° C., between about 600° C. to about 700° C., between about 700° C. to about 800° C., between about 800° C. to about 900° C., between about 900° C. to about 1000° C., between about 1000° C. to about 1100° C., between about 1100° C. to about 1200° C., of higher. The temperature of the thermal anneal process may also include any combination of these ranges (e.g., between about 700° C. and about 1100° C.) or may include any single value in these ranges (e.g., about 800° C.).

The time of the thermal anneal process may be adjusted and/or determined based on a depth of diffusion and the relative concentration of the P-dopant in the P-type region 552. For example, longer thermal anneal processes may cause the depth of diffusion to be greater. The diffusion depth may range from between about 10 nm to about 50 nm, between about 50 nm and about 100 nm, between about 100 nm and about 150 nm, between about 150 nm and about 200 nm, between 200 nm and about 400 nm, between about 400 nm and about 600 nm, between about 600 nm and about 800 nm, and/or between about 800 nm and 1 μm. The diffusion depth may also include any combination of these ranges (e.g., between about 100 nm about 200 nm) or any individual value in these ranges (e.g., about hundred 50 nm).

As described above, the charge balancing between the first N-type region 408 and the P-type region 452 may be based on the width of the regions and the relative doping concentrations. Since the width of the P-type region 452 will be relatively narrow (e.g., about 10% the width of the first N-type region 408), the doping concentration of the P-type region 452 may be relatively high in comparison to the first N-type region 408. For example, for a doping concentration of about 3e15 dopants/cm³ in the first N-type region 408, the doping concentration of the P-type region 452 may range from between about 5e15 dopants/cm³ to about 5e17 dopants/cm³ or higher, depending on the width. The doping concentration and the width of the P-type region 452 (e.g., the diffusion depth) may be adjusted to achieve the desired charge balancing for the super junction device.

FIG. 4D illustrates the removal of the P-doped layer 450, according to some embodiments. After the thermal anneal process, the p-doped layer 450 may be removed from the trench 433. This removal process may use a selective removal process that causes the p-doped layer 450 to be removed without removing any of the underlying material. For example, wet etch techniques may be used to remove the p-doped layer 450 without significantly removing any of the P-type region 452. At this stage, a P-type region 452 has been formed inside the N-type material that surrounds the trench 433. The vertical pillars of the P-type region 452 are significantly thinner than can be achieved using traditional etch and fill processes.

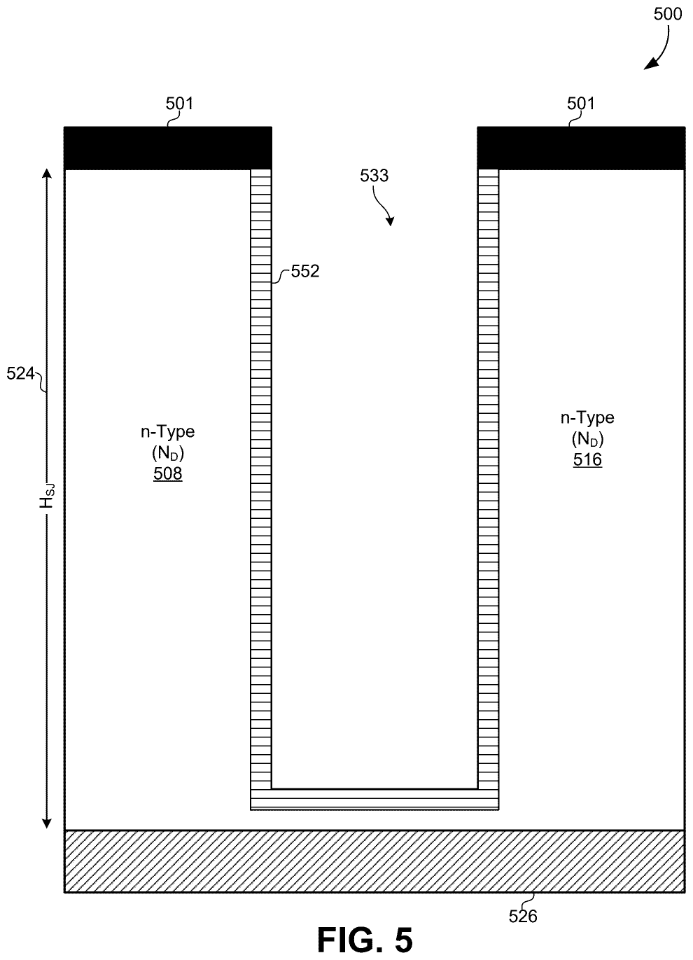

As described above, an alternate technique may be used in order to produce the P-type region in the N-type material of the trench. FIG. 5 illustrates how a P-type region 552 may be formed in the N-type material using a plasma doping (PLAD) technique, according to some embodiments. PLAD may offer the advantage of high-dose doping that is well-suited for sidewall doping solutions at high volumes. This technique may accelerate ions from the plasma by applying a high-voltage pulsed DC or direct-wave DC power supply and targeting the ions at the substrate, including the sidewalls of the trench 533. PLAD has been discovered to work well in high-aspect-ratio features, such as the trench 533.

While normal ion beam implantation techniques accelerate ions into a crystal lattice structure, then anneal the material to reform the crystal, a plasma doping process generates ions and radicals when the plasma is formed. The surface of the structure 500 may then be bombarded with the plasma particles, including the sidewalls of the trench 533. The dopants that are implanted with the PLAD process may result in a very shallow, but also very concentrated doping at the surface of the sidewalls of the trench 533. Specifically, the depth of diffusion may be tightly controlled using the PLAD process in comparison to other implant processes. Additionally, the doping depth may be more abrupt when using PLAD compared to other techniques, which usually exhibit a tailing-off of the doping concentration as the depth increases. As illustrated in FIG. 5, the P-type dopants may be implanted directly into the sidewalls of the trench 533, as well as the bottom of the trench 533.

As discussed above in relation to FIG. 4C, a thermal anneal process may also be carried out on the structure 500 that used the PLAD process. For example, a thermal anneal of between about 700° C. and about 1100° C. may be performed to increase the diffusion depth of the dopants and reform the lattice of the material. The thermal anneal may be carried out using any of the parameters discussed above.

FIG. 4E illustrates the formation of a passivation layer 455 as part of an optional operation that may be added to the method 300 in some embodiments. The passivation layer 455 may be formed by providing an oxygen-containing precursor to the processing region. The oxygen-containing precursor may be any number of precursors that may oxidize on the P-type region 452. As non-limiting examples, the oxygen-containing precursor may be or include diatomic oxygen, ozone, nitrous oxide, nitric oxide, sulfur dioxide or any other oxygen-containing precursors which may be delivered with or without plasma enhancement, and may be used to oxidize a depth of the existing material, or may be delivered with any other precursor, such as a silicon-containing precursor to deposit an oxide layer. The passivation layer 455 may be formed by using any deposition or growth method. The oxygen-containing material in the passivation layer 455 may oxidize and passivate at least a portion of the P-type region 452. The passivation layer 455 may serve to protect the P-type region 452 during subsequent etch operations. Alternatively, the passivation layer 455 may comprise a protective dielectric layer. Materials such as a thermal oxide, a silicon oxide formed using ALD, a metal oxide formed using ALD, SiNx formed using ALD, or a CVD/PE CVD oxide nitride may be formed as the passivation layer 455. The passivation layer 455 may be referred to as a protective oxide layer.

FIG. 4F illustrates the result of a directional etch to remove the P-type region 452 from the bottom of the trench 433. The portion of the P-type region 452 that is removed may be located at a bottom of the trench 433. In addition to the portion of the P-type region 452 that is removed, a portion of the passivation layer 455 may also be removed. The portion of the passivation layer 455 that is removed may be located at a bottom of the trench 433. In some embodiments, removing the portion of the P-type region 452 may include an anisotropic etching process, such as a reactive-ion etching operation or any other directional dry etch process. For example, the method 300 may include applying bias power to etch the bottom of the passivation layer 455 and/or the P-type region 452. The etching of the passivation layer 455 may be due to a sputtering of the oxide in the passivation layer 455, while a more chemical-based removal may occur through the p-type silicon, or vice versa. The bottom of the passivation layer 455 may be sputtered and removed at a faster rate than the sidewalls of the passivation layer 455 due to the anisotropicity of the etch. Therefore, this operation may remove the P-type region 452 and the passivation layer 455 from the bottom of the trench 433 while leaving the P-type region 452 (and at least a portion of the passivation layer 455 along the sidewall portion of the trench 433. This may expose the surface of the substrate 426 at the bottom of the trench 433, or may leave a portion of the N-type material on the bottom of the trench 433 as illustrated in FIG. 4F.

FIG. 4G illustrates the removal of the remaining portion of the passivation layer 455, according to some embodiments. The method 300 may optionally include removing the remaining portion of the passivation layer 455. The portion of the passivation layer 455 that is removed may be located along sidewalls of the trench 453 and overlying P-type region 452. In some embodiments, removing the portion of the passivation layer 455 may include, as one non-limiting example, a wet etching operation using any wet etching reagent(s), such as halogen-containing materials. However, it is contemplated that other forms of etching may alternatively or additionally be utilized including dry etch processes.

The remaining P-type region 452 may be present in the sidewalls of the trench 453. The P-type region 452 may be characterized by an aspect ratio of greater than or about 50, greater than or about 100, greater than or about 150, greater than or about 200, greater than or about 250, greater than or about 300, greater than or about 350, greater than or about 400, or more. With taller, narrower features than conventional methods, super junction devices formed using these structures may be characterized by reduced on-resistance due to the separation distances between N-type regions, and may be characterized by increased breakdown voltages due to the depth and uniformity of the P-type pillars formed.

The method 300 may include filling the trench 433 with an N-type material to form a second N-type region 412 such that a P-type region 451 is between the first N-type region 408 and the second N-type region 412 (308). FIG. 5H illustrates the formation of the second N-type region 412, according to some embodiments. The second N-type region 412 may fill the trench 433 by backfilling the internal region of the trench 433 between the sidewalls on which the P-type region 451 has been formed. The second N-type region 412 may fill the trench 433 free of any voids and without intermittent etching based on the increased width that may be afforded from the initial trench formation (e.g., about 4 μm). The second N-type region 412 may be the same material as the first N-type region 408. Together, the first N-type region 408 and the second N-type region 412 may at least partially surround the P-type region 451. The P-type region 451 may now from one of the active P-type pillars in the super junction device. The trench 433 may be filled with N-type material through an epitaxial growth process. For example, the exposed substrate 426 or N-type material at the bottom of the trench 433 may provide a base for epitaxially growing N-type silicon material up from the substrate 526 to fill the trench 533. As an alternative to silicon, the N-type material used for the super junction device may instead use silicon carbide. For example, the fill material forming the second N-type region 412 may include n-SiC for silicon carbide-based super junction devices.

A ratio of a width of the second N-type region 412 to a width of the P-type region 451 may be greater than or about 15, and may be greater than or about 20, greater than or about 22, greater than or about 24, greater than or about 26, greater than or about 28, greater than or about 30, or more. The ratio between the two materials may lead to a reduction of on-resistance in subsequent devices produced with these structures, as previously discussed. Alternatively stated, a width 457 of the P-type region 451 may be less than or about 10% of a combined width of the P-type region 451 and the second N-type region 412. The width 457 of the P-type region 451 may also be less than or about 9%, less than or about 8%, less than or about 7%, less than or about 6%, less than or about 5%, and so forth, of this combined width. For example, a P-type region 451 with a width 457 of 200 nm may be formed with a second N-type region 412 with a width 454 that is 3.8 μm in a trench that is 4.0 μm wide and 80 μm high.

Additional operations may include removing a portion of the N-type material and any remaining mask material by planarizing the structure, such as with a chemical-mechanical polishing operation. The method may also optionally include forming the remaining contact regions for the structure 400. FIG. 41 illustrates the structure 400 with contact regions, according to some embodiments. The structure 400 may include a gate region 402 and/or a source region 406 to complement a drain region formed by the substrate 426. The P-type region 451 may be disposed between the first N-type region 408 and the second N-type region 412 with a much thinner width. To maintain the proper charge balance, the doping level of the P-type region 451 may be increased accordingly. The doping level of the first N-type region 408 and/or the second N-type region 412 may remain the same as for the 650 V device in FIG. 2. For example, the doping level of the first N-type region 408 may be region may be between about 1e14 dopants/cm³ and about 1e16 dopants/cm³. The doping level of the P-type region 451 may be greater than or about 8 times, greater than or about 9 times, greater than or about 10 times, and so forth, of the doping level of the first N-type region 408.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a pillar” includes a plurality of such pillars, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMS, EEPROMs, magnetic or optical cards, flash memory, or other types of machine-readable mediums suitable for storing electronic instructions. Alternatively, the methods may be performed by a combination of hardware and software.

What is claimed is:

1. A method of forming a super junction device, the method comprising:
forming a first N-type material on a substrate;
etching a trench in the first N-type material, wherein the trench forms at least a first N-type region from the first N-type material;
causing a sidewall of the trench comprising the first N-type region to be doped with a P-type dopant to form a P-type region in the first N-type region; and
filling the trench with a second N-type material to form a second N-type region such that the P-type region is between the first N-type region and the second N-type region.

2. The method of claim 1, wherein causing the sidewall of the first N-type region in the trench to be doped with the P-type dopant also causes a bottom of the trench to be doped with the P-type dopant.

3. The method of claim 1, wherein etching the trench in the first N-type material causes the trench to extend down from a top surface of the first N-type material, and a bottom of the trench comprises at least a portion of the first N-type material between the bottom of the trench and the substrate such that the substrate is not exposed at the bottom of the trench.

4. The method of claim 1, further comprising forming a protective oxide layer on the P-type region and a bottom of the trench.

5. The method of claim 4, wherein the protective oxide layer is between about 5 nm and about 15 nm thick and is formed conformally inside of the trench.

6. The method of claim 1, further comprising performing a directional etch downward into the trench to remove a P-doped region at a bottom of the trench without removing the P-type region along the sidewall of the trench.

7. The method of claim 6, further comprising removing a protective oxide layer on the P-type region after performing the directional etch, wherein the directional etch also removes a protective oxide layer on the bottom of the trench.

8. The method of claim 6, wherein the directional etch does not expose a top surface of the substrate at a bottom of the trench.

9. A method of forming a super junction device, the method comprising:
etching a trench in a first N-type material on a substrate, wherein the trench forms at least a first N-type region from the first N-type material;
forming a P-doped layer on a sidewall of the trench comprising the first N-type region, wherein the P-doped layer comprises a P-type dopant;
annealing the P-doped layer sufficiently to cause the P-type dopant to diffuse into the first N-type region, thereby forming a P-type region in the first N-type region; and
filling the trench with a second N-type material to form a second N-type region such that the P-type region is between the first N-type region and the second N-type region.

10. The method of claim 9, wherein the P-doped layer comprises boron-doped silicon oxide formed using a deposition operation.

11. The method of claim 9, wherein the P-doped layer comprises boron-doped silicon nitride formed using a deposition operation.

12. The method of claim 9, wherein the P-doped layer comprises borophosphosilicate (BPSG) glass.

13. The method of claim 9, wherein the P-doped layer is between about 50 nm and 150 nm thick.

14. The method of claim 9, wherein annealing the doped layer comprises applying a temperature that is between about 700° C. and about 1100° C.

15. The method of claim 9, wherein the P-type dopant diffuses into the first N-type region to a depth of between about 100 nm and about 200 nm.

16. The method of claim 9, wherein the P-type dopant diffuses into the first N-type region to a concentration of between about 5e16 atoms/cm³ and about 5e17 atoms/cm³.

17. A method of forming a super junction device, the method comprising:
etching a trench in a first N-type material, wherein the trench forms at least a first N-type region in the first N-type material;
performing a plasma doping (PLAD) operation on a sidewall of the trench comprising the first N-type region, wherein the PLAD operation dopes the sidewall with a P-type dopant;
annealing the sidewall sufficiently to cause the P-type dopant to diffuse into the first N-type region, thereby forming a P-type region in the first N-type region; and
filling the trench with a second N-type material to form a second N-type region such that the P-type region is between the first N-type region and the second N-type region.

18. The method of claim 17, wherein a height of the P-type region is greater than or about 70 μm.

19. The method of claim 17, wherein a combined width of the P-type region and the second N-type region is less than or about 4 μm.

20. The method of claim 17, wherein an aspect ratio of an area occupied by second the N-type region and the P-type region is less than or about 20.
